(19) United States
(12) Patent Application Publication
(10) Pub. No.: US 2024/0413798 A1
(43) Pub. Date: Dec. 12, 2024

(54) AMPLIFIER STARVED HEATER COMPRESSION

(71) Applicant: Peavey Electronics Corporation, Meridian, MS (US)

(72) Inventors: Hartley Peavey, Meridian, MS (US); John C. Fields, Collinsville, MS (US)

(21) Appl. No.: 18/736,301

(22) Filed: Jun. 6, 2024

Related U.S. Application Data
(60) Provisional application No. 63/472,148, filed on Jun. 9, 2023.

(51) Int. Cl. H03F 3/181

(52) U.S. Cl. CPC H03F 3/181; H03F 2200/03

(57) ABSTRACT

The present invention achieves a major component of desirable tube guitar amplifier distortion by allowing for reduced filament/heater voltages to the output tubes in any amplifier design.

### RELATED APPLICATIONS

The present application claims priority to, and fully incorporates by reference herein, United States Provisional Patent Application No. 63/472,148, entitled VARIABLE AMPLIFIER TUBE FILAMENTS, filed on Jun. 9, 2023.

### FIELD OF THE INVENTION

The present invention relates to the control of output tube filaments in guitar tube amplifiers.

### BACKGROUND OF THE INVENTION

In a typical vacuum tube audio amplifier circuit, the filament (or heater) is the part of the electrical design that is usually taken for granted by circuit designers as the most basic element that is required to make the tube operate properly. Furthermore, in tube guitar amplifier circuits, the filament is the only element within a vacuum tube that typically runs at a fixed or static AC or DC voltage (or a combination of the two) and draws a steady current once it reaches its normal operating temperature. Once the tube reaches its operating temperature (with other appropriate voltages applied), it is fully operational, with respect to its function in the circuit. The function of the tube filament is to heat the cathode to generate free electrons. Typically, the only time that a filament voltage is varying in a typical circuit, is when power is first applied, during warm up.

The general tolerance specification for tube filaments is that their supply voltage should be able to vary by +/−10%, in normal operation. For a 6.3V filament, that means that it is accepted that the filament voltage can vary from 5.7 to 6.9V with no positive or negative effects on the other functions of the tube. One of skill in the art would not heat voltages outside of this range because higher voltages adversely decrease the life of the filament and lower voltages do not ensure that the tube will operate. Furthermore, when a typical receiving tube filament is completely off or cold, its resistance (in Ohms) is usually about 5-10 times lower than when it is on or hot. It follows that there is a filament warm up process that brings it to the optimal point of operation.

Regarding the basic operation of a tube, the filament/heater is seldom considered by the amplifier designer once the power supply is designed. Universal design practice has been to adhere to a tube's specifications for its various voltage requirements. It is widely known that higher heater/filament voltages result in drastically shortened tube life, with no obvious benefits to the sound or operation of the tube. Conversely, lower filament voltages can result in increased tube life, but this has not been done deliberately in the past since it is not regarded as a correct design practice for the tube's proper operation. Proper operation or proper design specifications are determined by each individual amplifier.

Moreover, if the filament voltage were to continue to be lowered, it would eventually reach a point where the tube's filament/heater would cease to operate, and the tube would cease to function. At some point in the process of reducing filament voltage, there will also be an area where the tube would still be operational, but the quantity of electrons being emitted from the cathode will be reduced so that the operation of the tube will be audibly affected. When the filament is operating in this area, the cathode of the tube will not be able to provide as many free electrons for the plate to attract with increasing signal levels. The result of this heater voltage reduction is increasing non-linear distortion. This can also be exacerbated by the fact that the power transformer's loading (under high signal level conditions) further starves the tube of electrons being emitted from the cathode. Even more of the same relationship takes place between the cathode and plate, and it follows that there is an extremely complex and non-linear distortion quality to a tube guitar amplifier (which is pleasing to many guitarists). Furthermore, the added non-linear effects that result from this reduced filament/heater voltage arrangement will result in very desirable sonic qualities in tube guitar amplifier listening tests.

There is no art that is relevant to the issues addressed by the present invention. U.S. Pat. No. 2,805,385 to McBean simply describes a method of filament adjustment for use in transmitting oscillators to account for periods of high-power dissipation; U.S. Pat. No. 10,063,194 to Quan is primarily concerned with reduction of plate and screen voltages in receiving tubes that are designed to run at high voltages. There is no mention in Quan of specifically reducing the filament supply for non-linear distortion effects. Quan only specifies that all tubes mentioned have power supplied to their filaments to provide thermionic emission, but this reference does not teach intentional lowering of filament/heater voltage. U.S. Pat. No. 11,128,262, also to Quan, is also not relevant, as it discusses the same issues as U.S. Pat. No. 10,063,194 to Quan, with one additional claim that specifies specific tube types.

Thus, there is a need for the present invention, which, in brief, takes advantage of the fact that an output tube's filament voltage operating at the lower limits of its tolerance (and beyond) will thus affect the overall response of the vacuum tube guitar power amplifier in a musically pleasing way and, additionally, will substantially increase the life of the output tubes as an additional benefit.

### SUMMARY OF THE INVENTION

The present invention takes advantage of the phenomenon that occurs in the filament/heater voltage supply and puts it under the control of the musician with none of the destructive effects that can result from simply using a globally variable AC mains supply, which varies all voltages in the amplifier. The present invention provides the desired sonic effects by lowering the filament voltage of the power tubes, keeping all other parameters in the amplifier the same. In summary, the present invention achieves the favorable distortion characteristics so desired by many guitarists by reducing the filament voltage to the power tubes in any amplifier design without any of the negative and destructive effects of using a globally variable AC mains supply.

### BRIEF DESCRIPTION OF DRAWINGS

FIG. 1 is a circuit diagram that illustrates an embodiment of the invention that is used in a typical linear power supply in a typical tube guitar amplifier.

FIG. 2 is a circuit diagram that illustrates an embodiment of the invention that provides a method of reducing the heater voltage used in a typical linear power supply in a typical tube guitar amplifier.

### DETAILED DESCRIPTION

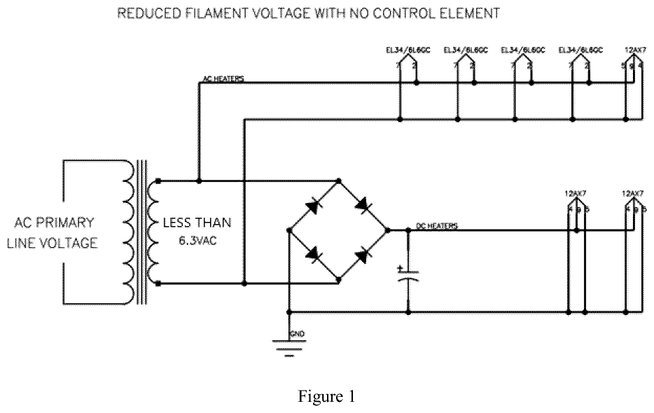

As discussed above, the present invention takes advantage of the phenomenon that occurs in the filament circuit and can put it under the control of the musician. The present invention provides the desired sonic effects by lowering the power tube's filament/heater voltage, while other parameters in the amplifier are held constant. In summary, the present invention achieves the major component of these desirable sonic effects by reducing the filament voltage to the output tubes in any tube guitar amplifier design without any of the negative and destructive effects of using a variable global AC mains supply. In addition, one concept of an embodiment of this invention, is to simply use less voltage on the output tube heaters directly from the transformer, rather than using a variable or a switched heater supply. An amplifier of the present invention can employ a lower voltage to the tube heaters directly from the transformer with no switch or variable element (see FIG. 1). In this embodiment, simply lowering the heater supply would accomplish the desired effect without any switch or control element, even though such operation is regarded as poor design practice. Simply stated, an embodiment of the present invention is the use of decreased heater supply regardless of how it is achieved, e.g., fixed, switched, or variable.

FIG. 1 illustrates a circuit diagram of an embodiment of the invention that is used in a typical linear power supply in a typical tube guitar amplifier. As shown in this circuit, a filament voltage that is lower than the tube manufacturer's recommended specification is supplied directly by a linear or switch mode power supply.

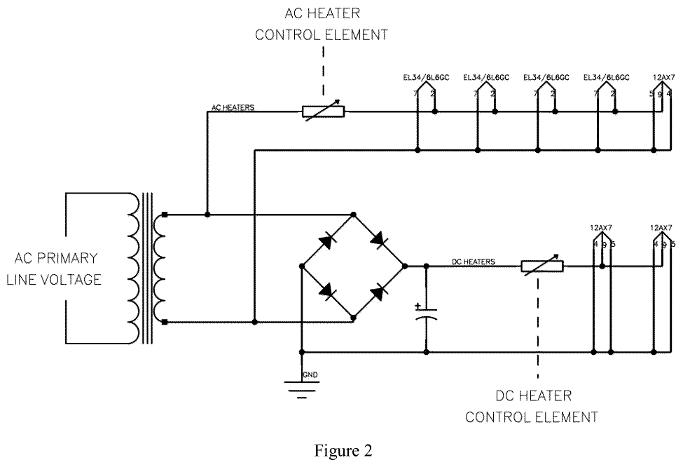

FIG. 2 illustrates a circuit diagram of an embodiment of the invention that is used in a typical power supply in a typical tube guitar amplifier. As shown in this circuit, the filament/heater voltage is supplied by a power supply (linear or switch mode). The AC HEATER CONTROL ELEMENT can be any active or passive electrical device that can provide a means to lower the AC voltage presented to the power tubes on the AC filament supply. Likewise, a DC HEATER CONTROL ELEMENT can be any active or passive electrical device that could be used to lower the DC voltage presented to the output tubes on a DC filament supply.

Still further embodiments are within the scope and spirit of the present invention, and include by way of example: a lowered filament/heater supply comprising alternating current, direct current, or any combination thereof; a filament supply comprising a linear or switching technology that reduces the filament voltage; a filament supply that is continuously variable, switched in steps that represent predetermined levels, or is operated at a lower-than-normal fixed level; a digital simulation of filament supply control that achieves the same effect that is achieved by analog hardware by implementation of a central processing unit or digital signal processing; a method of lowering power tube filament voltage by providing an active or passive electronic circuitry or an electromechanical device; a method of producing desired sonic effects from a tube guitar power amplifier by lowering filament/heater voltage and keeping all other parameters in the amplifier to the proper operation or proper design specifications are determined by each individual amplifier; a method of producing desired sonic effects in a guitar amplifier by lowering the power tube filament/heater voltage; an amplifier design that produces a desired non-linear distortion effect without the negative and or destructive effects of using a Globally Variable AC mains supply; a method of producing direct sonic effects by maintaining the tube amplifier filament/heater voltage at a lowered fixed level; a method of producing a desired non-linear distortion effect created by a tube amplifier by incrementally reducing the filament/heater voltage in the power tubes or by maintaining the filament/heater voltage at a fixed lower level; and a method of providing an amplifier with desired sonic effects by maintaining a lowered filament/heater voltage in the output tubes.

We claim:

1. A lowered filament/heater supply comprising alternating current, direct current, or any combination thereof.

2. The filament supply of claim 1 comprising a linear or switching technology that reduces a filament voltage.

3. The filament supply of claim 1 that is continuously variable, switched in steps that represent predetermined levels, or is operated at a lower-than-normal fixed level.

4. A digital simulation of filament supply control that achieves an effect that is achieved by analog hardware by implementation of a central processing unit or digital signal processing.

5. A method of lowering power tube filament voltage by providing an active or passive electronic circuitry or an electromechanical device.

6. A method of producing desired sonic effects from a tube guitar power amplifier by lowering filament/heater voltage and keeping all other parameters in the amplifier to a proper design specification.

7. A method of producing desired sonic effects in a guitar amplifier by lowering a power tube filament/heater voltage.

8. The method of claim 7 wherein the amplifier produces a desired non-linear distortion effect without a negative and or destructive effects of using a Globally Variable AC mains supply.

9. A method of producing direct sonic effects by maintaining a tube amplifier filament/heater voltage at a lowered fixed level.

10. A method of producing a desired non-linear distortion effect created by a tube amplifier by incrementally reducing a filament/heater voltage in power tubes or by maintaining the filament/heater voltage at a fixed lower level.

11. A method of providing an amplifier with desired sonic effects by maintaining a lowered filament/heater voltage in output tubes.
